(19) United States
(12) Patent Application Publication
(10) Pub. No.: US 2024/0387599 A1
(43) Pub. Date: Nov. 21, 2024

(54) NANOSCALE HOLES FOR PIXEL SENSORS AND METHODS OF FORMING THE SAME

(71) Applicant: Taiwan Semiconductor Manufacturing Company, Ltd, Hsinchu (TW)

(72) Inventors: Wei-Lin CHEN, Tainan City (TW); Chun-Hao CHOU, Tainan City (TW); Kun-Hui LIN, Tainan City (TW); Kuo-Cheng LEE, Tainan City (TW)

(21) Appl. No.: 18/319,064

(22) Filed: May 17, 2023

(51) Int. Cl. H01L 27/146

(52) U.S. Cl. CPC H01L 27/14645; H01L 27/14621; H01L 27/1463; H01L 27/14649; H01L 27/14685; H01L 27/14689

(57) ABSTRACT

An array of nanoscale structures over photodiodes of a pixel array improves quantum efficiency (QE) for shorter wavelengths of light, such as green light and blue light. The nanoscale structures may be used without high absorption (HA) structures (e.g., when the pixel array is configured only for visible light) or may at least partially surround HA structures (e.g., when the pixel array is configured both for visible light and near infrared light). Additionally, the array of nanoscale structures may be formed using photolithography such that the nanoscale structures are approximately spaced at regular intervals. Therefore, QE for the pixel array is improved more than if the array of nanoscale structures were to be formed using a random (or quasi-random) process.

### BACKGROUND

Complementary metal oxide semiconductor (CMOS) image sensors utilize light-sensitive CMOS circuitry to convert light energy into electrical energy. The light-sensitive CMOS circuitry may include a photodiode formed in a silicon substrate. As the photodiode is exposed to light, an electrical charge is induced in the photodiode (referred to as a photocurrent). The photodiode may be coupled to a switching transistor, which is used to sample the charge of the photodiode. Colors may be determined by placing filters over the light-sensitive CMOS circuitry.

Light received by pixel sensors of a CMOS image sensor is often based on the three primary colors: red, green, and blue (R, G, B). Pixel sensors that sense light for each color can be defined through the use of a color filter that allows the light wavelength for a particular color to pass into a photodiode. Some pixel sensors may include a near infrared (NIR) pass filter, which blocks visible light and passes NIR light through to the photodiode.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example pixel array described herein.

FIGS. 3A-3C are diagrams of example semiconductor structures described herein.

FIGS. 4A-4M are diagrams of an example implementation described herein.

FIGS. 5A-5D are diagrams of an example implementation described herein.

FIG. 6 is a diagram of example components of one or more devices of FIG. 1 described herein.

FIG. 7 is a flowchart of an example process associated with forming a semiconductor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A pixel array (e.g., a back side illumination (BSI) complementary metal oxide semiconductor (CMOS) image sensor and/or another type of CMOS image sensor) may be configured to detect visible light (e.g., light with a wavelength in a range from approximately 380 nanometers (nm) to approximately 750 nm), near infrared (NIR) light (e.g., light with a wavelength in a range from approximately 700 nm to approximately 1400 nm), or a combination thereof. In order to improve quantum efficiency (QE) of the pixel array, high absorption (HA) structures may be formed over photodiodes of the pixel array. In particular, angled walls of the HA structures may modify or change an orientation of a refractive interface of the pixel array. This change in orientation results in a smaller angle of refraction relative to planar portions for the same angle of incidence of incident light. As a result, the HA structures direct wider angles of incident light towards the photodiodes. The HA structures particularly improve QE for longer wavelengths of light, such as red light and NIR light.

Some implementations described herein provide techniques and apparatuses for forming an array of nanoscale structures over photodiodes of a pixel array. The nanoscale structures improve QE for shorter wavelengths of light, such as green light and blue light, because the nanoscale structures are smaller than HA structures. The nanoscale structures may be used without HA structures (e.g., when the pixel array is configured only for visible light) or may at least partially surround HA structures (e.g., when the pixel array is configured both for visible light and NIR light).

Additionally, the array of nanoscale structures may be formed using photolithography such that the nanoscale structures are approximately spaced at regular intervals. Therefore, QE for the pixel array is improved more than if the array of nanoscale structures were to be formed using a random (or quasi-random) process, such as directed self-assembly (DSA).

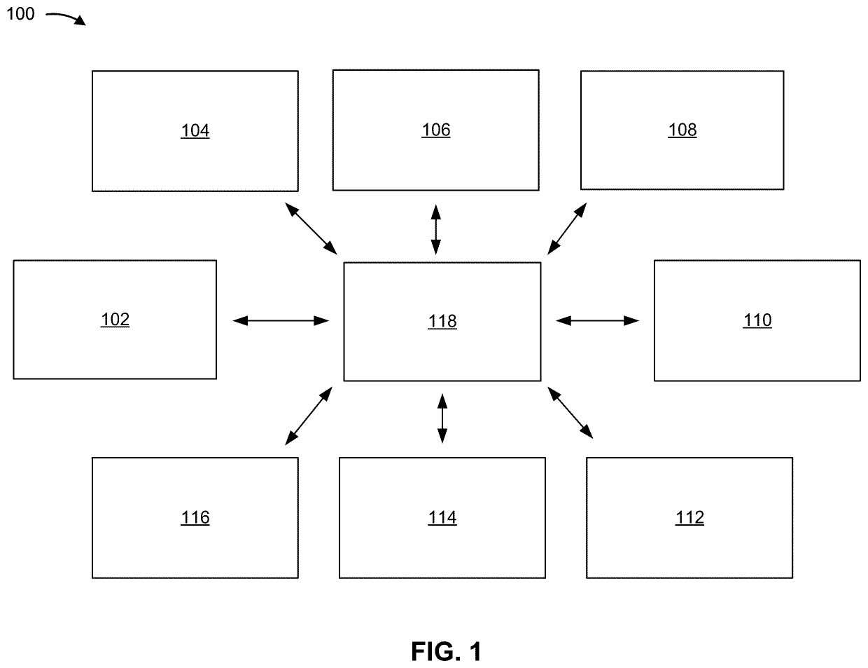

FIG. 1 is a diagram of an example environment 100 in which systems and/or methods described herein may be implemented. As shown in FIG. 1, environment 100 may include a plurality of semiconductor processing tools 102-116 and a wafer/die transport tool 118. The plurality of semiconductor processing tools 102-116 may include a deposition tool 102, an exposure tool 104, a developer tool 106, an etch tool 108, a planarization tool 110, a plating tool 112, a photoresist removal tool 114, an annealing tool 116, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, an epitaxy tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The photoresist removal tool 114 is a semiconductor processing tool that is capable of removing remaining portions of a photoresist layer from a substrate after the etch tool 108 removes portions of the substrate. For example, the photoresist removal tool 114 may use a chemical stripper and/or another technique to remove a photoresist layer from a substrate.

The annealing tool 116 is a semiconductor processing tool that includes a semiconductor processing chamber and one or more devices capable of heating a semiconductor substrate or semiconductor device. For example, the annealing tool 116 may include a rapid thermal annealing (RTA) tool or another type of annealing tool that is capable of heating a semiconductor substrate to cause a reaction between two or more materials or gasses, to cause a material to decompose. As another example, the annealing tool 116 may be configured to heat (e.g., raise or elevate the temperature of) a structure or a layer (or portions thereof) to re-flow the structure or the layer, or to crystallize the structure or the layer, to remove defects such as voids or seams. As another example, the annealing tool 116 may be configured to heat (e.g., raise or elevate the temperature of) a layer (or portions thereof) to enable bonding of two or more semiconductor devices.

The wafer/die transport tool 118 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 118 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

In some implementations, one or more of the semiconductor processing tools 102-116 and/or the wafer/die transport tool 118 may perform one or more semiconductor processing operations described herein. For example, one or more of the semiconductor processing tools 102-116 and/or the wafer/die transport tool 118 may form a hardmask layer over a substrate including a photodiode, deposit a first material over the hardmask layer in a first rectangular pattern, deposit a second material along sidewalls of the first rectangular pattern, remove the first material such that the second material remains in a second rectangular pattern, deposit a third material along sidewalls of the second rectangular pattern, remove the second material such that the third material remains in a third rectangular pattern, etch the hardmask layer to extend the third rectangular pattern into the hardmask layer, remove the third material such that the hardmask layer remains in the third rectangular pattern, perform lithography to form an array of nanoscale holes in the substrate using the hardmask layer, and/or form an array of nanoscale structures by depositing a dielectric material in the array of nanoscale holes, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. For example, the deposition tool 102 may include the plating tool 112. Additionally, or alternatively, a set of devices (e.g., one or more devices) of the example environment 100 may perform one or more functions described as being performed by another set of devices of the example environment 100.

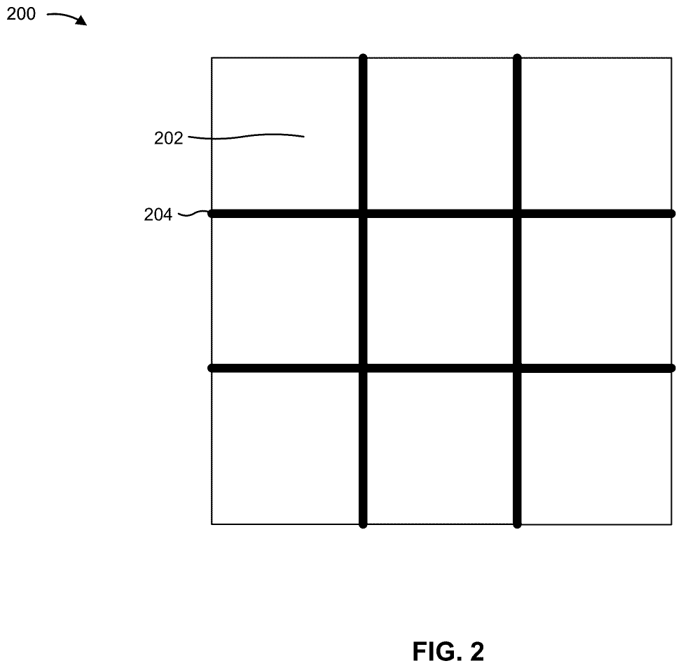

FIG. 2 is a diagram of an example pixel array 200 (or a portion thereof) described herein. The pixel array 200 may be included in an image sensor, such as a CMOS image sensor, a BSI CMOS image sensor, or another type of image sensor.

FIG. 2 shows a top-down view of the pixel array 200. As shown in FIG. 2, the pixel array 200 may include a plurality of pixel sensors 202. As further shown in FIG. 2, the pixel sensors 202 may be arranged in a grid. In some implementations, the pixel sensors 202 are square-shaped (as shown in the example in FIG. 2). In some implementations, the pixel sensors 202 include other shapes such as circle shapes, octagon shapes, diamond shapes, and/or other shapes.

The pixel sensors 202 may be configured to sense and/or accumulate incident light (e.g., light directed toward the pixel array 200). For example, a pixel sensor 202 may absorb and accumulate photons of the incident light in a photodiode. The accumulation of photons in the photodiode may generate a charge representing the intensity or brightness of the incident light (e.g., a greater amount of charge may correspond to a greater intensity or brightness, and a lower amount of charge may correspond to a lower intensity or brightness).

The pixel sensors 202 may be electrically and optically isolated by a deep trench isolation (DTI) structure 204 included in the pixel array 200. The DTI structure 204 may include a plurality of interconnected trenches that are filled with a dielectric material, such as an oxide material. The trenches of the DTI structure 204 may be included around the perimeters of the pixel sensors 202 such that the DTI structure 204 surrounds the pixel sensors 202, as shown in FIG. 2. Moreover, the trenches of the DTI structure 204 may extend into a substrate in which the pixel sensors 202 are formed to surround the photodiodes and other structures of the pixel sensors 202 in the substrate. As indicated above, the pixel array 200 may be included in a BSI CMOS image sensor. In these examples, the DTI structure 204 may include a back side DTI (BDTI) structure with a high aspect ratio that is formed from the back side of the pixel array 200.

The pixel array 200 may be electrically connected to a back-end-of-line (BEOL) metallization stack (not shown) of the image sensor. The BEOL metallization stack may electrically connect the pixel array 200 to control circuitry that may be used to measure the accumulation of incident light in the pixel sensors 202 and convert the measurements to an electrical signal.

As indicated above, FIG. 2 is provided as an example. Other examples may differ from what is described with regard to FIG. 2.

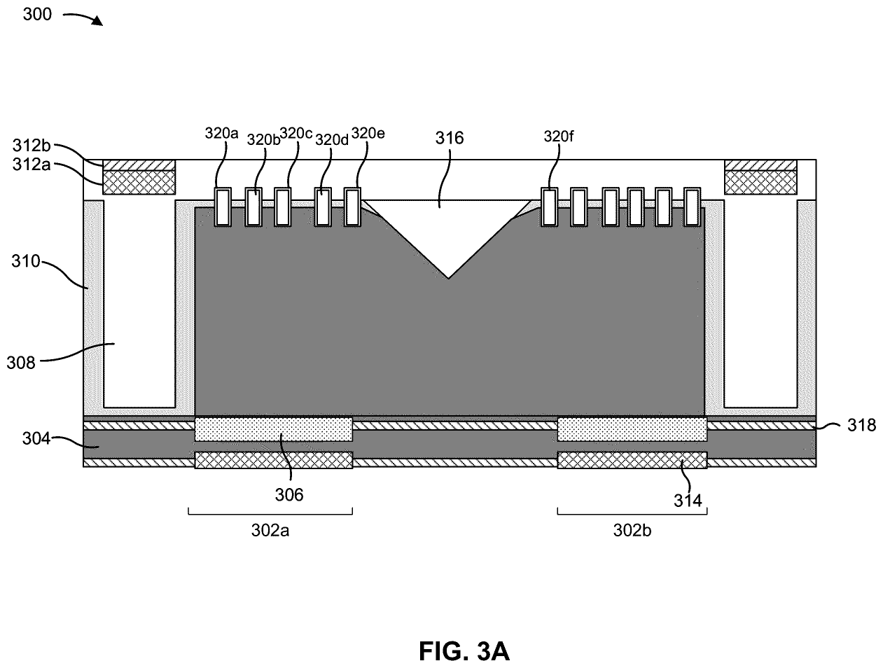

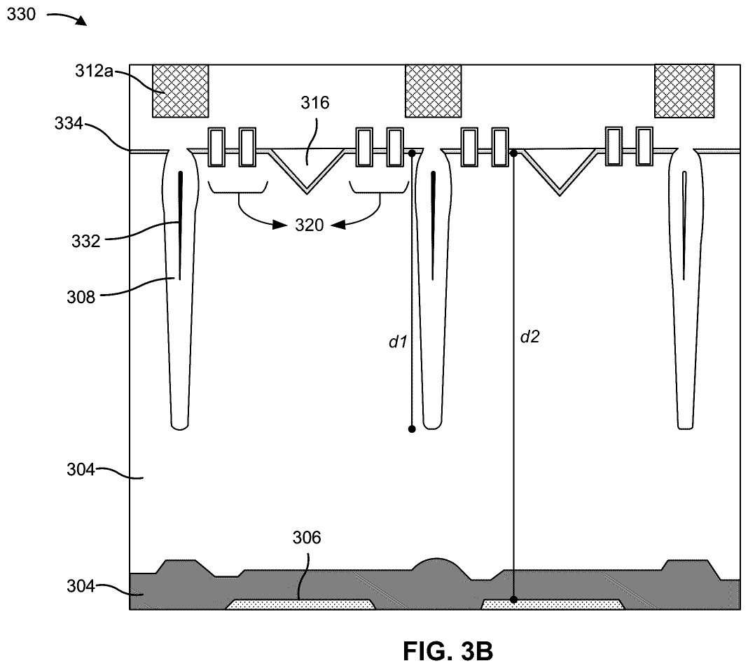

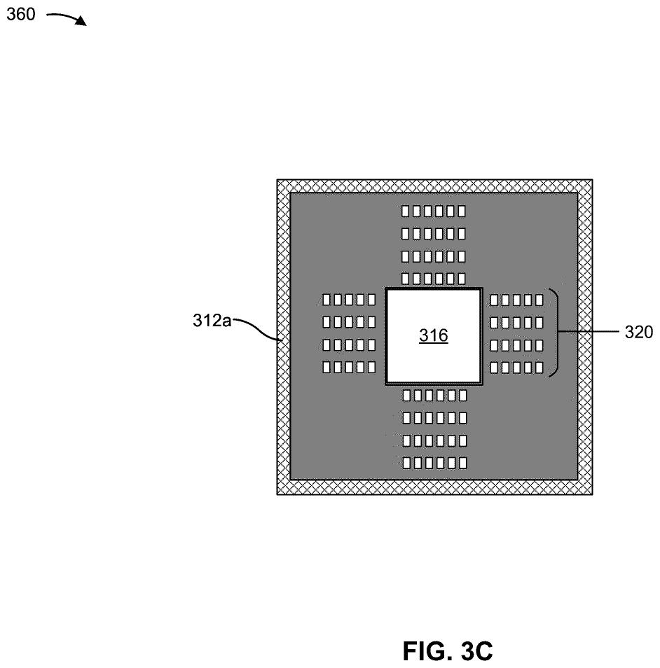

FIG. 3A is a diagram of an example pixel array 300 described herein. The example pixel array 300 has two photodiodes per pixel. In some implementations, the example pixel array 300 illustrated in FIG. 3A may include, or may be included in, the pixel array 200 (or a portion thereof). In some implementations, the pixel array 300 may be included in an image sensor. The image sensor may be a CMOS image sensor, a BSI CMOS image sensor, or another type of image sensor.

As shown in FIG. 3A, the pixel array 300 may include a plurality of adjacent pixel sensors 302, such as pixel sensors 302a and 302b. In some implementations, the pixel sensors 302a and 302b are configured as square-shaped pixel sensors 202 included in the pixel array 200. In some implementations, the pixel sensors 302a and 302b are configured as octagon-shaped pixel sensors and/or square-shaped pixel sensors. In some implementations, the pixel sensors 302a and 302b include additional or alternative shapes of pixel sensors or a combination thereof.

The pixel sensors 302 may be formed in a substrate 304, which may include a semiconductor die substrate, a semiconductor wafer, or another type of substrate in which semiconductor pixels may be formed. In some implementations, the substrate 304 is formed of silicon (Si), a material including silicon, a III-V compound semiconductor material such as gallium arsenide (GaAs), a silicon on insulator (SOI), or another type of semiconductor material that is capable of generating a charge from photons of incident light.

Each pixel sensor 302 may include a photodiode 306. A photodiode 306 may include a region of the substrate 304 that is doped with a plurality of types of ions to form a p-n junction or a PIN junction (e.g., a junction between a p-type portion, an intrinsic (or undoped) type portion, and an n-type portion). For example, the substrate 304 may be doped with an n-type dopant to form a first portion (e.g., an n-type portion) of a photodiode 306 and a p-type dopant to form a second portion (e.g., a p-type portion) of the photodiode 306. A photodiode 306 may be configured to absorb photons of incident light. The absorption of photons causes a photodiode 306 to accumulate a charge (referred to as a photocurrent) due to the photoelectric effect. Here, photons bombard the photodiode 306, which causes emission of electrons of the photodiode 306. The emission of electrons causes the formation of electron-hole pairs, where the electrons migrate toward the cathode of the photodiode 306 and the holes migrate toward the anode, which produces the photocurrent.

An isolation structure 308 may be included in the substrate 304 between adjacent pixel sensors. The isolation structure 308 may provide optical isolation by blocking or preventing diffusion or bleeding of light from one pixel sensor to another pixel sensor, thereby reducing crosstalk between adjacent pixel sensors. The isolation structure 308 may include trenches or DTI structures (e.g., DTI structure 204) that are coated or lined with an antireflective coating (ARC) 310 and filled with an oxide layer (e.g., over the ARC 310). The isolation structure 308 may be formed in a grid layout in which the isolation structure 308 extends around the perimeters of the pixel sensors 302 in the pixel array 300 and intersects at various locations of the pixel array 300. In some implementations, as shown in FIG. 3A, the isolation structure 308 may surround groups of pixel sensors (e.g., the pair of pixel sensors 302a and 302b in FIG. 3A). Alternatively, as described in connection with 3B, the isolation structure 308 may surround each pixel sensor individually.

The ARC 310 may be included within the isolation structures 308 and on the substrate 304 above the photodiodes 306. The ARC 310 may include a suitable material for reducing a reflection of incident light projected toward the photodiodes 306. For example, the ARC 310 may include nitrogen-containing material.

A metal layer 312a may be included above and/or on the isolation structure 308. The metal layer 312a may include a metallic material such as tungsten (W), copper (Cu), aluminum (Al), cobalt (Co), nickel (Ni), titanium (Ti), tantalum (Ta), another conductive material, and/or an alloy including one or more of the foregoing. The metal layer 312a may be etched such that a grid structure is formed between the pixel sensors 302 and over the isolation structure 308. The grid structure may include a plurality of interconnected columns of the metal layer 312a. The grid structure may surround the perimeters of the pixel sensors 302, and may be configured to provide additional crosstalk reduction and/or mitigation in combination with the isolation structure 308.

In some implementations, the grid structure may additionally or alternatively include a dielectric layer 312b. Accordingly, in one example, the grid structure may include a hybrid structure with the metal layer 312a and the dielectric layer 312b. The dielectric layer 312b may include an oxide material such as a silicon oxide (SiOₓ) (e.g., silicon dioxide (SiO₂)), a silicon nitride (SiNₓ), a silicon carbide (SiCₓ), a titanium nitride (TiNₓ), a tantalum nitride (TaNₓ), a hafnium oxide (HfOₓ), a tantalum oxide (TaOₓ), or an aluminum oxide (AlOₓ), or another dielectric material that is capable of providing additional crosstalk reduction and/or mitigation in combination with the isolation structure 308.

Each pixel sensor 302 may include a transfer gate 314 to control the transfer of photocurrent between the photodiode 306 and a drain region (not shown). The transfer gate 314 may be energized (e.g., by applying a voltage or a current to the transfer gate 314) to cause a conductive channel to form between the photodiode 306 and the drain region (and/or a drain extension region). The conductive channel may be removed or closed by de-energizing the transfer gate 314, which blocks and/or prevents the flow of photocurrent between the photodiode 306 and the drain region (and/or the drain extension region). Accordingly, the transfer gate 314 may facilitate electrical communication between the pixel sensor 302 and a BEOL metallization stack (not shown) used to measure the accumulation of incident light in the pixel sensor 302 and convert the measurement to an electrical signal.

The pixel array 300 may further include an HA structure 316 in the substrate 304. The HA structure 316 may be located near a center within a perimeter or inner boundary of the isolation structure 308 such that the HA structure 316 is located above and/or over the photodiodes 306. The HA structure 316 may include a shallow trench that is filled with a dielectric material, such as a silicon oxide (SiOₓ). The HA structure 316 may include a structure having angled walls such that the structure has an approximately pyramidal shape (e.g., exhibiting an approximately triangular shape in a cross-sectional view, as shown in FIG. 3A, and an approximately polygonal shape in a top-down view, such as an approximately rectangular shape, as shown in FIG. 3C, or an approximately triangular shape). As used herein, “pyramidal shape” refers to a structure with a polygonal base connected to a point or to a smaller polygon functions as an apex. The HA structure 316 may extend from a top surface of the substrate 304 into the substrate 304 toward the photodiodes 306.

The HA structure 316 may increase the absorption of incident light for the pixel array 300 (thereby increasing the quantum efficiency of the pixel array 300) by modifying or changing an orientation of a refractive interface of a portion of the top surface of the substrate 304. This change in orientation results in a smaller angle of refraction relative to planar portions for a same angle of incidence of incident light. As a result, the HA structure 316 directs wider angles of incident light toward the pixel sensors 302a and 302b than if no HA structure 316 were included in the pixel array 300.

In some implementations, an etch stop layer (ESL) 318 may prevent overetching of the substrate 304. An ESL includes a material that is resistant (or at least partially resistant) to particular types of dry etching and/or wet etching. An ESL may include a material that is resistant to etchants that may otherwise be used to etch other layers near the ESL. Selecting such a material provides etch selectivity and enables the ESL to remain unetched (or mostly unetched) while other layers are etched. For example, the ESL 318 may include a nitride (such as aluminum nitride (AlN) and/or silicon nitride (SiN)) and/or an oxide (such as a silicon oxynitride (SiOₓN_{y}), aluminum oxynitride (AlON), and/or a silicon oxide (SiOₓ)). In some implementations, the ESL 318 includes a plurality of ESLs stacked together and configured to function as a single ESL.

The pixel array 300 may further include nanoscale structures 320 (e.g., a nanoscale structure 320a, a nanoscale structure 320b, a nanoscale structure 320c, a nanoscale structure 320d, a nanoscale structure 320e, and a nanoscale structure 320f) in the substrate 304. As used herein, “nanoscale” refers to a dimension (e.g., a width and/or a height) that is smaller than approximately 100 nm. The nanoscale structures 320 may be located within the perimeter or inner boundary of the isolation structure 308 and are generally physically smaller than the DTI structure 308. The nanoscale structures 320 may be filled with a dielectric material, such as a silicon oxide (SiOₓ). In some implementations, the nanoscale structures 320 may be filled with a combination of materials that function as a dielectric. The nanoscale structures 320 are configured to decrease the amount of incident light that is reflected off of the top surface of the substrate 304 and are configured to refract incident light into the substrate 304 toward the photodiodes 306.

The HA structure 316 improves QE of the pixel array 300 for longer wavelengths of light, such as red light (e.g., incident light near a 650 nm wavelength) and NIR light (e.g., incident light in an NIR wavelength range). The nanoscale structures 320 improve QE for shorter wavelengths of light, such as green light (e.g., incident light near a 550 nm wavelength) and blue light (e.g., incident light near a 450 nm wavelength), because the nanoscale structures 320 are smaller than the HA structure 316.

FIG. 3B is a diagram of an example pixel array 330 described herein. The example pixel array 330 has one photodiode per pixel rather than two photodiodes per pixel. In some implementations, the example pixel array 330 illustrated in FIG. 3B may include, or may be included in, the pixel array 200 (or a portion thereof). In some implementations, the pixel array 330 may be included in an image sensor. The image sensor may be a CMOS image sensor, a BSI CMOS image sensor, or another type of image sensor.

The example pixel array 330 of FIG. 3B is similar to the example pixel array 300 of FIG. 3A. As shown in FIG. 3B, the isolation structure 308 surrounds each photodiode 306 individually, rather than in groups. Additionally, as shown in FIG. 3B, the isolation structure 308 includes voids 332 in each trench in order to further reduce crosstalk between adjacent pixel sensors.

As further shown in FIG. 3B, each trench in the isolation structure 308 may have a depth (e.g., represented by d1) relative to a top surface 334 of the substrate 304. The depth d1 may be in a range from approximately 3 micrometers (μm) to approximately 5 μm. Providing a depth of at least 3 μm provides electrical isolation between adjacent pixel sensors to reduce optical crosstalk. Providing a depth of no more than 5 μm keeps the photodiodes 306 undamaged during formation of the isolation structure 308. Additionally, each photodiode 306 may have a depth (e.g., represented by d2) relative to the top surface 334 of the substrate 304. The depth d2 may be in a range from approximately 5 μm to approximately 7 μm. Using a depth of at least 5 μm enables bulk silicon of the substrate 304 may perform photoelectric conversion of incoming photons to electrical current. Using a depth of no more than 7 μm allows the pixel array 330 to be miniaturized for inclusion in an electronic package. Therefore, a ratio of the depth d1 of the isolation structure 308 from the top surface 334 to the depth d2 of the photodiode 306 from the top surface 334 may be in a range from approximately 0.5 to approximately 0.8.

FIG. 3C is a diagram of an example pixel array 360 described herein. The example pixel array 360 is similar to the example pixel array 330 but is shown from a top view rather than a cross-sectional view. In some implementations, the example pixel array 360 illustrated in FIG. 3C may include, or may be included in, the pixel array 200 (or a portion thereof). In some implementations, the pixel array 360 may be included in an image sensor. The image sensor may be a CMOS image sensor, a BSI CMOS image sensor, or another type of image sensor.

FIG. 3C is a top-down view as compared with the cross-sectional views of FIGS. 3A and 3B. As shown in FIG. 3C, a top layer of the isolation structure (e.g., the metal layer 312a in FIG. 3C or the dielectric layer 312b in other examples) surrounds each photodiode (or group of photodiodes). Above each photodiode is the HA structure 316, and the HA structure 316 is at least partially surrounded by an array of the nanoscale structures 320.

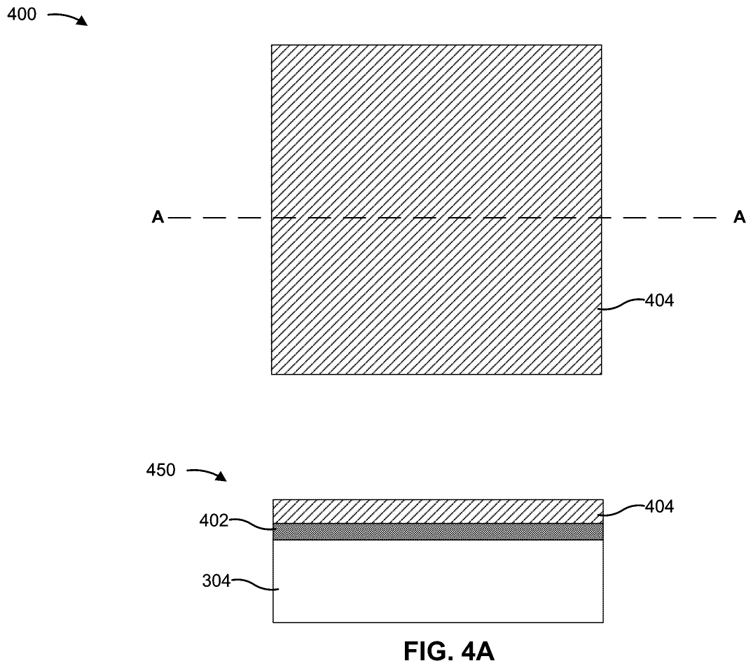

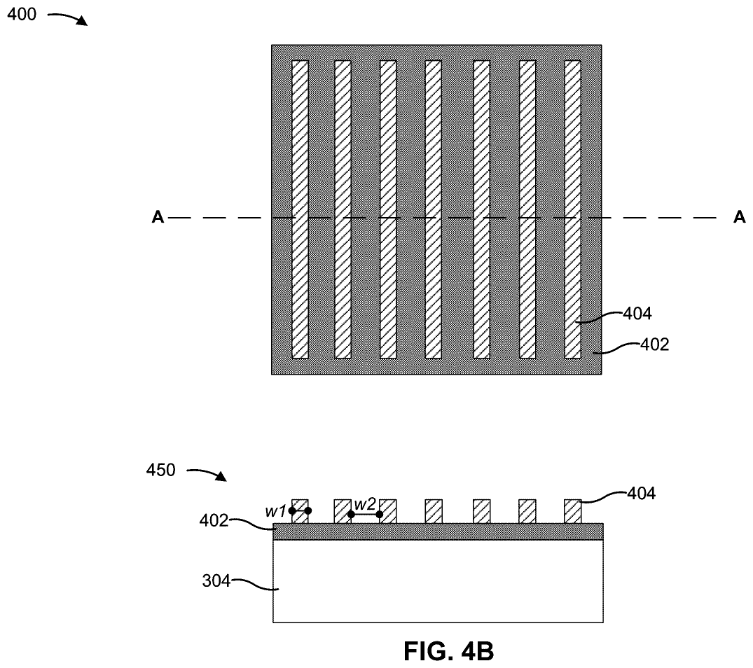

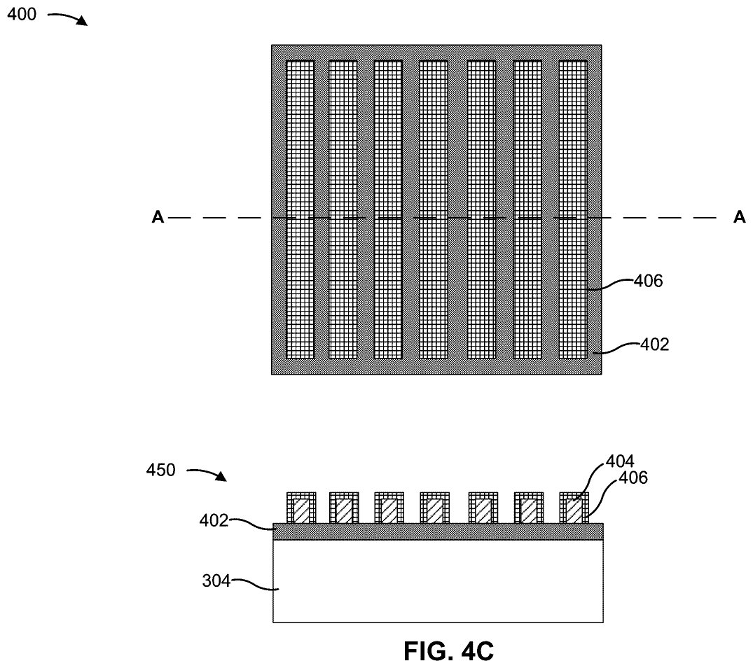

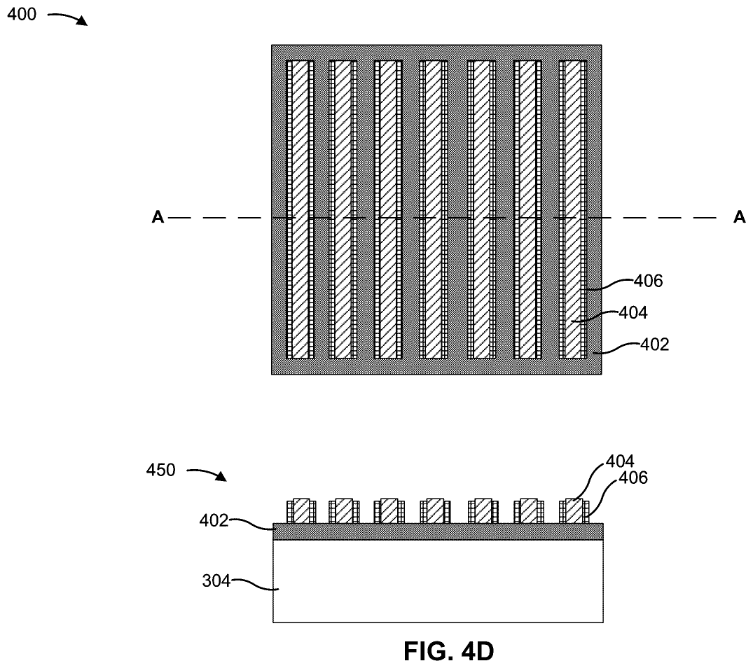

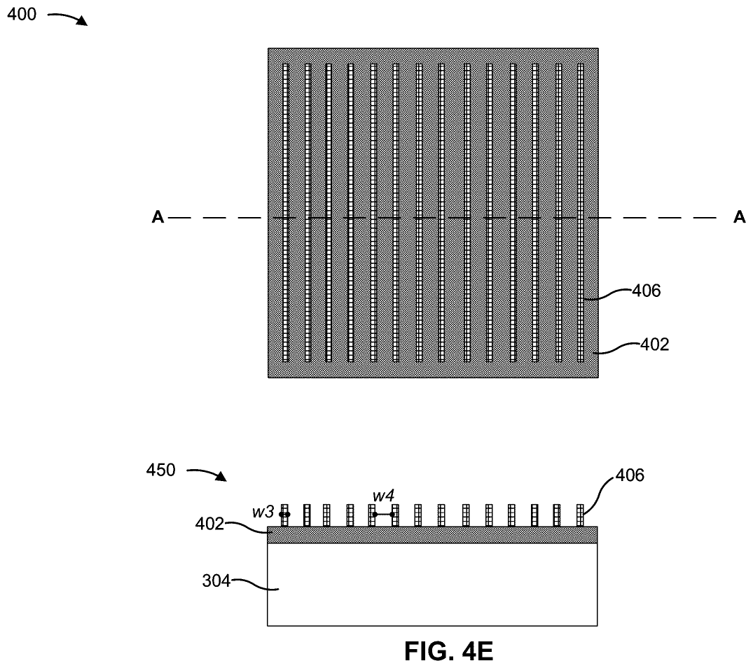

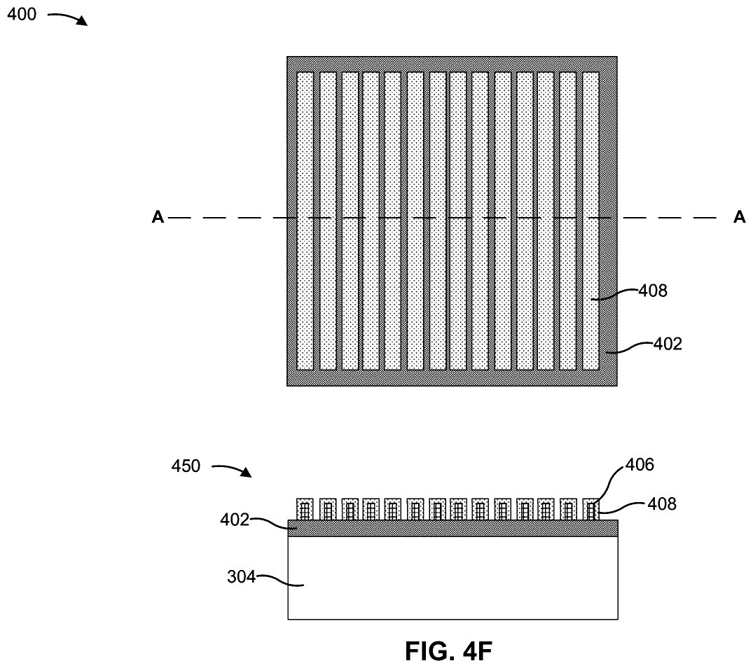

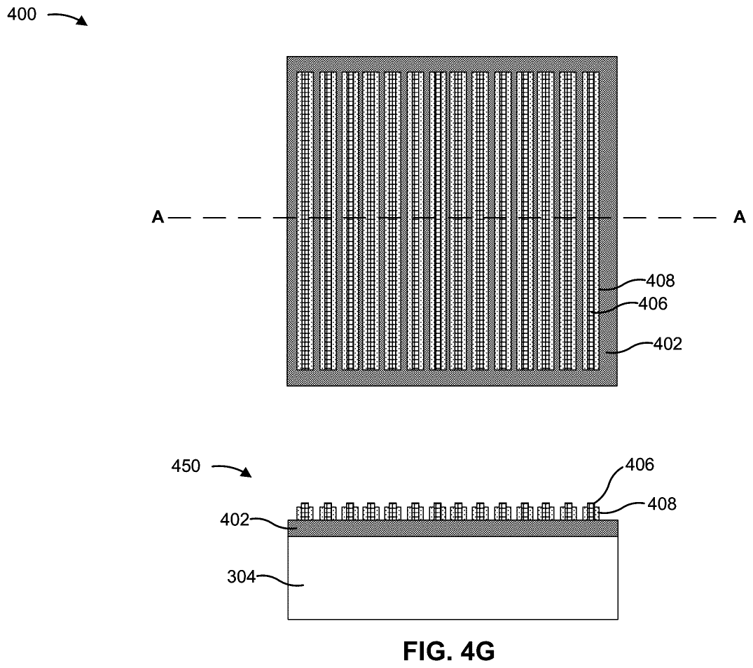

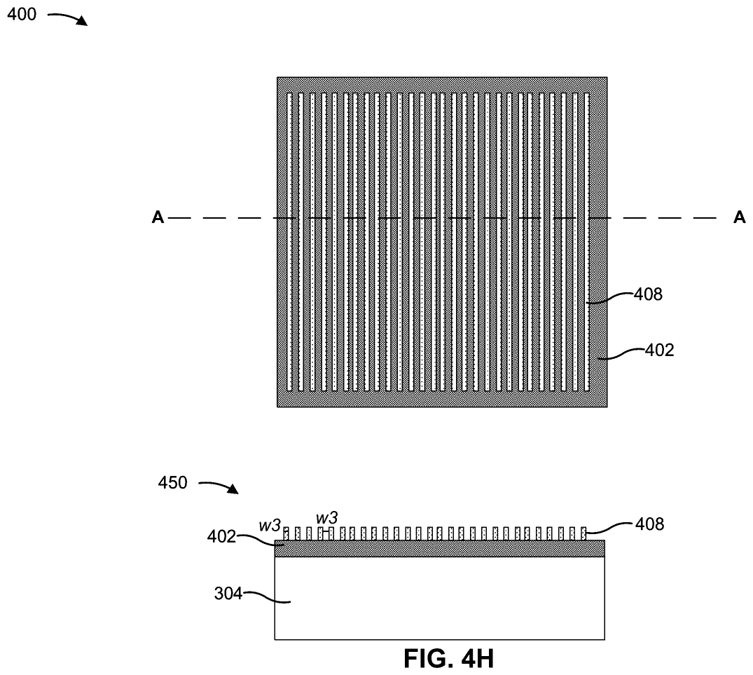

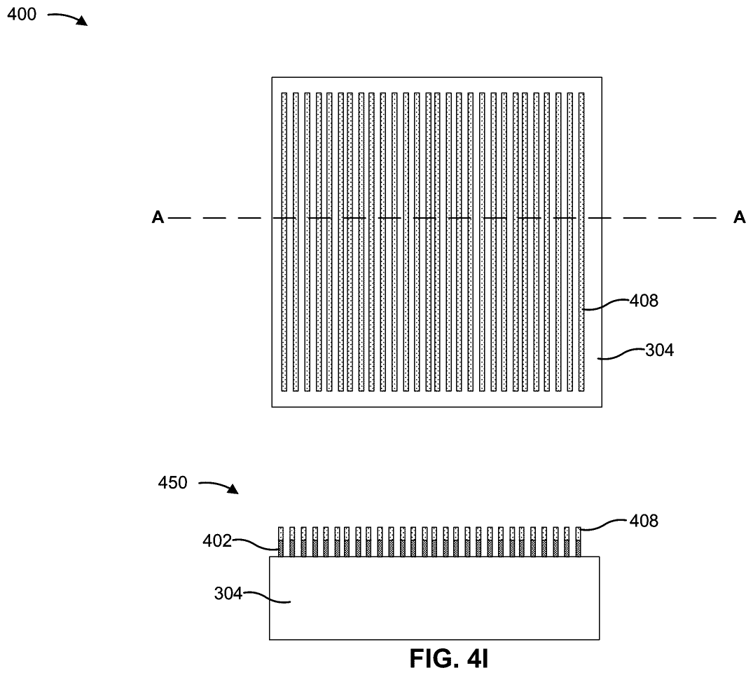

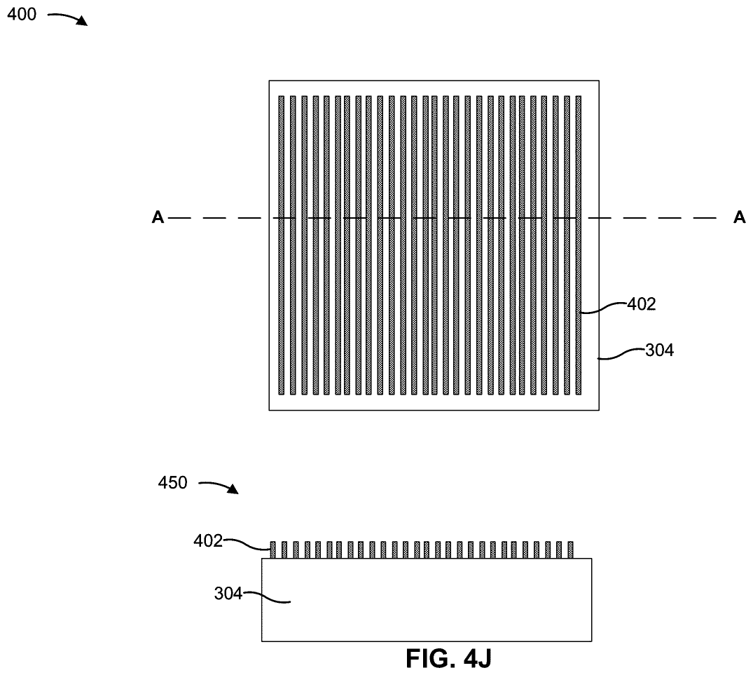

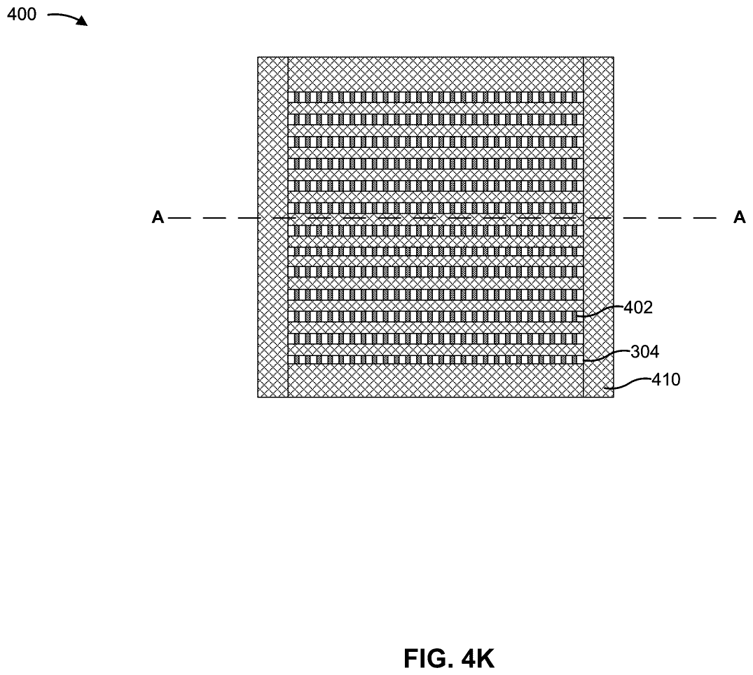

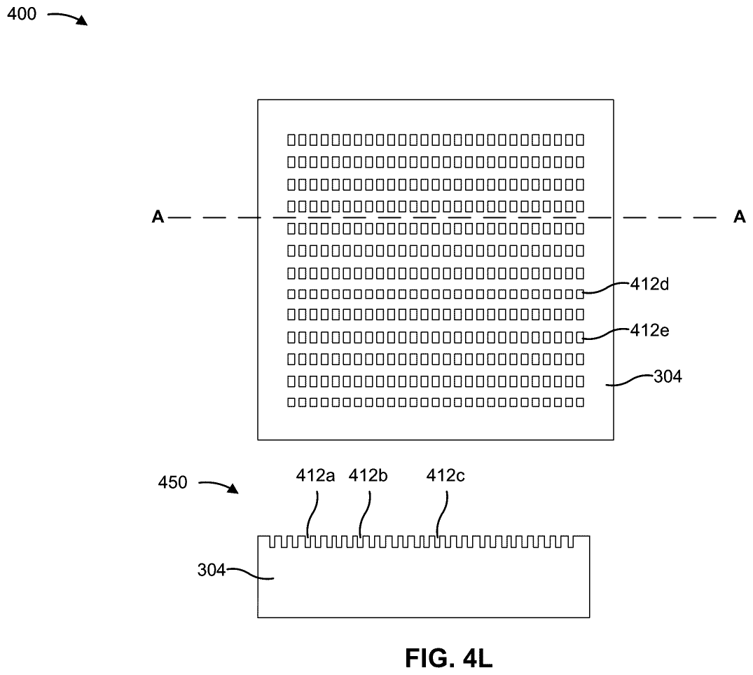

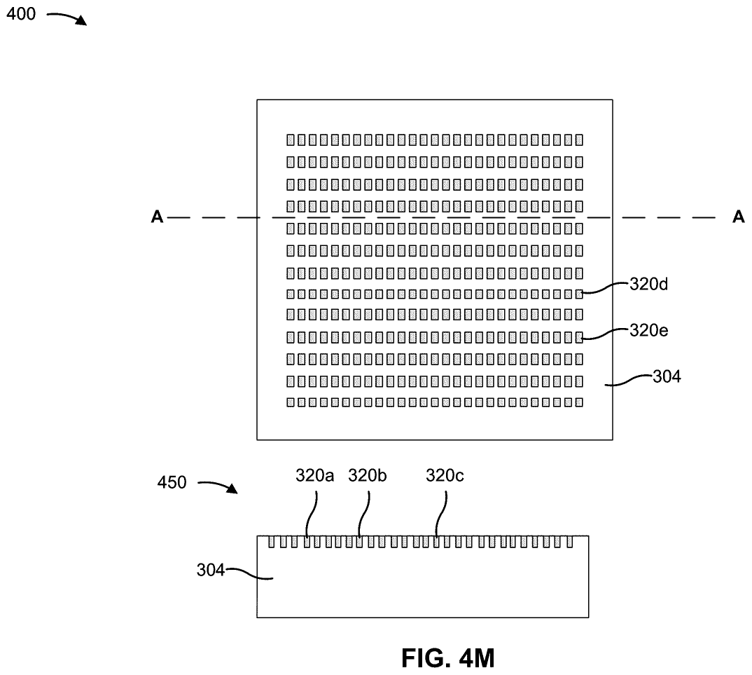

As further shown in FIG. 3C, the nanoscale structures 320 are approximately spaced at regular intervals. As used herein, “regular intervals” may refer to a distance between adjacent structures within a row being approximately equal (e.g., within 1%, 10%, or a similar margin of error) to a distance between other adjacent structures in the same row. Additionally, or alternatively, “regular intervals” may refer to a distance between adjacent structures within a column being approximately equal (e.g., within 1%, 10%, or a similar margin of error) to a distance between other adjacent structures in the same column. The array of nanoscale structures 320 may be approximately spaced at regular intervals because the nanoscale structures 320 are patterned via photolithography, as described in connection with FIGS. 4A-4M, rather than via a random (or quasi-random) process.

As indicated above, FIGS. 3A-3C are provided as examples. Other examples may differ from what is described with regard to FIGS. 3A-3C.

FIGS. 4A-4M are diagrams of an example implementation 400 described herein. The example implementation 400 may be an example process or method for forming the pixel array 300. The example implementation 400 may include a patterning technique for forming the array of nanoscale structures 320 of the pixel array 300. The patterning technique described in connection with FIGS. 4A-4M results in nanoscale structures 320 that are approximately spaced at regular intervals.

FIGS. 4A-4J illustrate a top-down view of the pixel array for example implementation 400 and a cross-sectional view 450 along the line AA. As shown in FIG. 4A, the example process for forming the pixel array may be performed in connection with a substrate 304.

As described above, the substrate 304 may include a semiconductor die substrate, a semiconductor wafer, a stacked semiconductor wafer, or another type of substrate in which semiconductor pixels may be formed. For example, the substrate 304 may be formed of silicon (Si) (e.g., a silicon substrate), a material including silicon, a III-V compound semiconductor material such as gallium arsenide (GaAs), an SOI, or another type of semiconductor material that is capable of generating a charge from photons of incident light. In some implementations, the substrate 304 is formed of a doped material (e.g., a p-doped material or an n-doped material) such as a doped silicon.

Additionally, the substrate 304 may have a photodiode formed therein. The photodiode is not shown in FIGS. 4A-4M because the photodiode would be deeper in the substrate 304 than shown. Additionally, an isolation structure (e.g., a DTI structure) may be included in the substrate 304 at least partially surrounding the photodiode. The isolation structure 308 is not shown in FIGS. 4A-4M because the isolation structure would surround the portion of the substrate 304 that is shown.

As shown in FIG. 4A, a hardmask layer 402 may be formed over the substrate 304. For example, the deposition tool 102 may form the hardmask layer 402 over and/or on the frontside surface of the substrate 304 (e.g., over a top surface of the substrate 304). The hardmask layer 402 may include a metal material, an oxide material (e.g., a silicon oxide (SiOₓ)), and/or another type of dielectric material. In some implementations, the hardmask layer 402 may include a high-κ material. Examples of high-k dielectric materials include high-k metal oxides such as a hafnium oxide (HfOₓ), an aluminum oxide (AlₓO_{y}), a zirconium oxide (ZrOₓ), a magnesium oxide (MgOₓ), a yttrium oxide (YₓO_{y}), a tantalum oxide (TaₓO_{y}), a titanium oxide (TiOₓ), a lanthanum oxide (LaₓO_{y}), a barium oxide (BaOₓ), or another type of high-k metal oxide. In some implementations, the deposition tool 102 may form the hardmask layer 402 using a spin-coating technique, a CVD technique, a PVD technique, an ALD technique, and/or another deposition technique.

As further shown in FIG. 4A, a first material 404 may be formed over the hardmask layer 402. For example, the deposition tool 102 may form the first material 404 over and/or on the frontside surface of the substrate 304 (e.g., over the hardmask layer 402). The first material 404 may include a metal (e.g., titanium nitride (TiN), tungsten (W), and/or aluminum (Al), among other examples) and/or another material that may be etched separately from the hardmask layer 402 (e.g., by using a different etchant and/or a different etching technique). In some implementations, the deposition tool 102 may form the first material 404 using a spin-coating technique, a CVD technique, a PVD technique, an ALD technique, and/or another deposition technique.

As shown in FIG. 4B, a portion of the first material 404 may be removed. For example, the deposition tool 102 may form a photoresist layer over and/or on the frontside surface of the first material 404, the exposure tool 104 may expose the photoresist layer to a radiation source to form a pattern on the photoresist layer, and the developer tool 106 may develop and remove portions of the photoresist layer to expose the pattern. Accordingly, the etch tool 108 may etch a portion of the first material 404. For example, the etch tool 108 may use a wet etch technique, a dry etch technique, a plasma-enhanced etch technique, and/or another type of etch technique to etch the portion of the first material 404. The photoresist removal tool 114 may remove the remaining portions of the photoresist layer (e.g., using a chemical stripper, a plasma asher, and/or another technique) after the etch tool 108 removes the portion of the first material 404.

As further shown in FIG. 4B, the first material 404 may remain in a first rectangular pattern. In the example implementation 400, the first rectangular pattern is shorter along a direction parallel to the line AA as compared with a direction perpendicular to the line AA. In some implementations, the first rectangular pattern of the first material 404 may include structures with a width (e.g., represented by w1). The width w1 may be in a range from approximately 50 nm to approximately 80 nm. Providing a width of at least 50 nm provides sufficient sidewall area for deposition of a second material 406 (e.g., as described in connection with FIG. 4C). Providing a width of no more than 80 nm allows for formation of nanoscale structures (e.g., as described in connection with FIG. 4M) rather than larger structures. Additionally, adjacent structures of the first rectangular pattern may be separated from each other by a width (e.g., represented by w2). The width w2 may be in a range from approximately 60 nm to approximately 120 nm. Providing a width of at least 60 nm allows for formation of nanoscale structures (e.g., as described in connection with FIG. 4M) that are separate from each other. Providing a width of no more than 120 nm allows for formation of nanoscale structures (e.g., as described in connection with FIG. 4M) that are sufficiently dense to improve QE of the pixel array for visible light. Therefore, a ratio of the width w1 of the first material 404 from the width w2 between portions of the first material 404 may be in a range from approximately 0.4 to approximately 0.8.

As shown in FIG. 4C, the second material 406 may be formed over the first rectangular pattern. For example, the deposition tool 102 may form the second material 406 over and/or on the frontside surface of the substrate 304 (e.g., over the first material 404). The second material 406 may include a nitride (e.g., silicon nitride (Si₃N₄), among other examples) and/or another material that may be selectively deposited on the first material 404. Therefore, as shown in FIG. 4C, the second material 406 is deposited on top surfaces and sidewalls of the first rectangular pattern but not on exposed surfaces of the hardmask layer 402. Additionally, the second material 406 may include a material that can be etched separately from the hardmask layer 402 (e.g., by using a different etchant and/or a different etching technique). In some implementations, the deposition tool 102 may form the second material 406 using a spin-coating technique, a CVD technique, a PVD technique, an ALD technique, and/or another deposition technique.

As shown in FIG. 4D, a portion of the second material 406 may be removed. For example, the deposition tool 102 may form a photoresist layer over and/or on the frontside surface of the second material 406, the exposure tool 104 may expose the photoresist layer to a radiation source to form a pattern on the photoresist layer, and the developer tool 106 may develop and remove portions of the photoresist layer to expose the pattern. Accordingly, the etch tool 108 may etch a portion of the second material 406. For example, the etch tool 108 may use a wet etch technique, a dry etch technique, a plasma-enhanced etch technique, and/or another type of etch technique to etch the portion of the second material 406. The photoresist removal tool 114 may remove the remaining portions of the photoresist layer (e.g., using a chemical stripper, a plasma asher, and/or another technique) after the etch tool 108 removes the portion of the second material 406.

Alternatively, the etch tool 108 may perform an anisotropic etch cycle (e.g., using a plasma or another type of dry etch) to remove the portion of the second material 406 on the top surfaces of the first rectangular pattern. As a result, the second material 406 remains only on sidewalls of the first rectangular pattern.

As shown in FIG. 4E, the first material 404 may be removed. For example, the deposition tool 102 may form a photoresist layer over and/or on the frontside surface of the first material 404, the exposure tool 104 may expose the photoresist layer to a radiation source to form a pattern on the photoresist layer, and the developer tool 106 may develop and remove portions of the photoresist layer to expose the pattern. Accordingly, the etch tool 108 may etch the first material 404. For example, the etch tool 108 may use a wet etch technique, a dry etch technique, a plasma-enhanced etch technique, and/or another type of etch technique to etch the first material 404. The photoresist removal tool 114 may remove the remaining portions of the photoresist layer (e.g., using a chemical stripper, a plasma asher, and/or another technique) after the etch tool 108 removes the first material 404.

Alternatively, the etch tool 108 may perform an isotropic etch cycle (e.g., using a dry etch or a wet etch) to remove the first material 404. For example, the second material 406 may be selected for resistivity the etchant and/or the etching technique used to remove the first material 404. As a result, the second material 406 remains in a second rectangular pattern. In the example implementation 400, the second rectangular pattern is shorter along a direction parallel to the line AA as compared with a direction perpendicular to the line AA. In some implementations, the second rectangular pattern of the second material 406 may include structures with a width (e.g., represented by w3). The width w3 may be in a range from approximately 10 nm to approximately 40 nm. Providing a width of at least 10 nm provides sufficient sidewall area for deposition of a third material 408 (e.g., as described in connection with FIG. 4F). Providing a width of no more than 40 nm allows for formation of nanoscale structures (e.g., as described in connection with FIG. 4M) rather than larger structures. Additionally, adjacent structures of the second rectangular pattern may be separated from each other by a width (e.g., represented by w4). The width w4 may be in a range from approximately 30 nm to approximately 120 nm. Providing a width of at least 30 nm allows for formation of nanoscale structures (e.g., as described in connection with FIG. 4M) that are separate from each other. Providing a width of no more than 120 nm allows for formation of nanoscale structures (e.g., as described in connection with FIG. 4M) that are sufficiently dense to improve QE of the pixel array for visible light. Therefore, a ratio of the width w3 of the second material 406 from the width w4 between portions of the second material 406 may be in a range from approximately 0.1 to approximately 0.3.

As shown in FIG. 4F, the third material 408 may be formed over the second rectangular pattern. For example, the deposition tool 102 may form the third material 408 over and/or on the frontside surface of the substrate 304 (e.g., over the second material 406). The third material 408 may include a metal material, an oxide material, and/or another material that may be selectively deposited on the second material 406. Therefore, as shown in FIG. 4F, the third material 408 is deposited on top surfaces and sidewalls of the second rectangular pattern but not on exposed surfaces of the hardmask layer 402. Additionally, the third material 408 may include a material that can be etched separately from the hardmask layer 402 (e.g., by using a different etchant and/or a different etching technique). In some implementations, the deposition tool 102 may form the third material 408 using a spin-coating technique, a CVD technique, a PVD technique, an ALD technique, and/or another deposition technique.

As shown in FIG. 4G, a portion of the third material 408 may be removed. For example, the deposition tool 102 may form a photoresist layer over and/or on the frontside surface of the third material 408, the exposure tool 104 may expose the photoresist layer to a radiation source to form a pattern on the photoresist layer, and the developer tool 106 may develop and remove portions of the photoresist layer to expose the pattern. Accordingly, the etch tool 108 may etch a portion of the third material 408. For example, the etch tool 108 may use a wet etch technique, a dry etch technique, a plasma-enhanced etch technique, and/or another type of etch technique to etch the portion of the third material 408. The photoresist removal tool 114 may remove the remaining portions of the photoresist layer (e.g., using a chemical stripper, a plasma asher, and/or another technique) after the etch tool 108 removes the portion of the third material 408.

Alternatively, the etch tool 108 may perform an anisotropic etch cycle (e.g., using a plasma or another type of dry etch) to remove the portion of the third material 408 on the top surfaces of the second rectangular pattern. As a result, the third material 408 remains only on sidewalls of the second rectangular pattern.

As shown in FIG. 4H, the second material 406 may be removed. For example, the deposition tool 102 may form a photoresist layer over and/or on the frontside surface of the second material 406, the exposure tool 104 may expose the photoresist layer to a radiation source to form a pattern on the photoresist layer, and the developer tool 106 may develop and remove portions of the photoresist layer to expose the pattern. Accordingly, the etch tool 108 may etch the second material 406. For example, the etch tool 108 may use a wet etch technique, a dry etch technique, a plasma-enhanced etch technique, and/or another type of etch technique to etch the second material 406. The photoresist removal tool 114 may remove the remaining portions of the photoresist layer (e.g., using a chemical stripper, a plasma asher, and/or another technique) after the etch tool 108 removes the second material 406.

Alternatively, the etch tool 108 may perform an isotropic etch cycle (e.g., using a dry etch or a wet etch) to remove the third material 408. For example, the third material 408 may be selected for resistivity the etchant and/or the etching technique used to remove the second material 406. As a result, the third material 408 remains in a third rectangular pattern. In the example implementation 400, the third rectangular pattern is shorter along a direction parallel to the line AA as compared with a direction perpendicular to the line AA. In some implementations, the third rectangular pattern of the second material 406 may include structures with a width (e.g., represented by w3). The width w3 may be in a range from approximately 10 nm to approximately 40 nm. Providing a width of at least 10 nm allows for formation of nanoscale structures (e.g., as described in connection with FIG. 4M) that are large enough to improve QE for visible light. Providing a width of no more than 40 nm allows for formation of nanoscale structures (e.g., as described in connection with FIG. 4M) rather than larger structures. Additionally, adjacent structures of the third rectangular pattern may be separated from each other by a width (e.g., represented by w3). The width w3 may be in a range from approximately 10 nm to approximately 40 nm. Providing a width of at least 10 nm allows for formation of nanoscale structures (e.g., as described in connection with FIG. 4M) that are separate from each other. Providing a width of no more than 40 nm allows for formation of nanoscale structures (e.g., as described in connection with FIG. 4M) that are sufficiently dense to improve QE of the pixel array for visible light. Therefore, a ratio of the width of the second material 406 from the width between portions of the second material 406 may be in a range from approximately 0.1 to approximately 0.3. For example, the width of the third material 408 may be approximately equal to the width between portions of the third material 408, as shown in FIG. 4H.

As shown in FIG. 4I, a portion of the hardmask layer 402 may be removed. For example, the deposition tool 102 may form a photoresist layer over and/or on the frontside surface of the hardmask layer 402, the exposure tool 104 may expose the photoresist layer to a radiation source to form a pattern on the photoresist layer, and the developer tool 106 may develop and remove portions of the photoresist layer to expose the pattern. Accordingly, the etch tool 108 may etch the portion of the hardmask layer 402. For example, the etch tool 108 may use a wet etch technique, a dry etch technique, a plasma-enhanced etch technique, and/or another type of etch technique to etch the portion of the hardmask layer 402. The photoresist removal tool 114 may remove the remaining portions of the photoresist layer (e.g., using a chemical stripper, a plasma asher, and/or another technique) after the etch tool 108 removes the portion of the hardmask layer 402.

Alternatively, the etch tool 108 may perform an anisotropic etch cycle (e.g., using a plasma or another type of dry etch) to remove the portion of the hardmask layer 402 that is not under remaining portions of the third material 408. For example, the third material 408 may be selected for resistivity the etchant and/or the etching technique used to remove the hardmask layer 402. As a result, the third rectangular pattern is extended into the hardmask layer 402. In some implementations, the third rectangular pattern is also extended into the substrate 304. For example, the etch tool 108 may perform etching until a time threshold is satisfied (e.g., by performing an etch cycle for an amount of time comprises the time threshold). Alternatively, an ESL may be present between the hardmask layer 402 and the substrate 304 in order to prevent etching of the substrate 304.

As shown in FIG. 4J, the third material 408 may be removed. For example, the deposition tool 102 may form a photoresist layer over and/or on the frontside surface of the third material 408, the exposure tool 104 may expose the photoresist layer to a radiation source to form a pattern on the photoresist layer, and the developer tool 106 may develop and remove portions of the photoresist layer to expose the pattern. Accordingly, the etch tool 108 may etch the third material 408. For example, the etch tool 108 may use a wet etch technique, a dry etch technique, a plasma-enhanced etch technique, and/or another type of etch technique to etch the third material 408. The photoresist removal tool 114 may remove the remaining portions of the photoresist layer (e.g., using a chemical stripper, a plasma asher, and/or another technique) after the etch tool 108 removes the third material 408.

Alternatively, the etch tool 108 may perform an isotropic etch cycle (e.g., using a dry etch or a wet etch) to remove the third material 408. For example, the hardmask layer 402 may be selected for resistivity the etchant and/or the etching technique used to remove the third material 408. As a result, the hardmask layer 402 remains in the third rectangular pattern.

As shown in FIG. 4K, a photoresist layer 410 may be formed over the substrate 304. For example, the deposition tool 102 may form the photoresist layer 410 over and/or on the frontside surface of the substrate 304 (e.g., over the hardmask layer 402 and exposed surfaces of the substrate 304). As further shown in FIG. 4K, the exposure tool 104 may expose the photoresist layer 410 to a radiation source to form a pattern on the photoresist layer 410, and the developer tool 106 may develop and remove portions of the photoresist layer 410 to expose the pattern. For example, the pattern may divide the third rectangular pattern such that exposed potions of the substrate 304 have cross-sections (e.g., in the top-down view) that are approximately square. As used herein, “square” refers to a polygon that has four approximately equal sides (e.g., within 1%, 10%, or a similar margin of error).

In some implementations, as shown in FIG. 4K, the pattern of the photoresist layer 410 may extend along a boundary corresponding to the isolation structure (not shown). Accordingly, the isolation structure is formed before the nanoscale structures 320. Alternatively, the isolation structure may be formed after the nanoscale structures 320 are formed.

FIGS. 4L and 4M illustrate a top-down view of the pixel array for example implementation 400 and a cross-sectional view 450 along the line AA. As shown in FIG. 4L, a portion of the substrate 304 may be removed. For example, the etch tool 108 may use a wet etch technique, a dry etch technique, a plasma-enhanced etch technique, and/or another type of etch technique to etch the substrate 304. The etch tool 108 may etch exposed portions of the substrate 304 according to the pattern of the photoresist layer 410. As a result, an array of nanoscale holes 412 (e.g., a nanoscale hole 412a, a nanoscale hole 412b, a nanoscale hole 412c, a nanoscale hole 412d, and a nanoscale hole 412e) are formed in the substrate 304.

As further shown in FIG. 4L, the photoresist removal tool 114 may remove the remaining portions of the photoresist layer 410 (e.g., using a chemical stripper, a plasma asher, and/or another technique) after the etch tool 108 removes the portion of the substrate 304. Additionally, as shown in FIG. 4L, the hardmask layer 402 may be removed. For example, the etch tool 108 may use a wet etch technique, a dry etch technique, a plasma-enhanced etch technique, and/or another type of etch technique to etch the hardmask layer 402.

As shown in FIG. 4M, the nanoscale holes 412 may be filled with dielectric material to form an array of nanoscale structures 320. The deposition tool 102 may deposit the dielectric material using a spin-coating technique, a CVD technique, a PVD technique, an ALD technique, and/or another deposition technique. In some implementations, the dielectric material may overflow the nanoscale holes 412 such that the planarization tool 110 removes dielectric material outside of the nanoscale holes 412 using a CMP technique.

Because the array of nanoscale holes 412 are small, the nanoscale structures 320 refract visible light toward the photodiode (not shown) of the pixel sensor. As a result, the array of nanoscale structures 320 increases QE of the pixel sensor for visible light.

As indicated above, FIGS. 4A-4M are provided as an example. Other examples may differ from what is described with regard to FIGS. 4A-4M. For example, in some implementations, the first material 404 may be patterned with smaller widths w1 and w2. As a result, a rectangular pattern of the second material 406 may be extended into the hardmask layer 402, without deposition of the third material 408, while still resulting in the nanoscale structures 320.

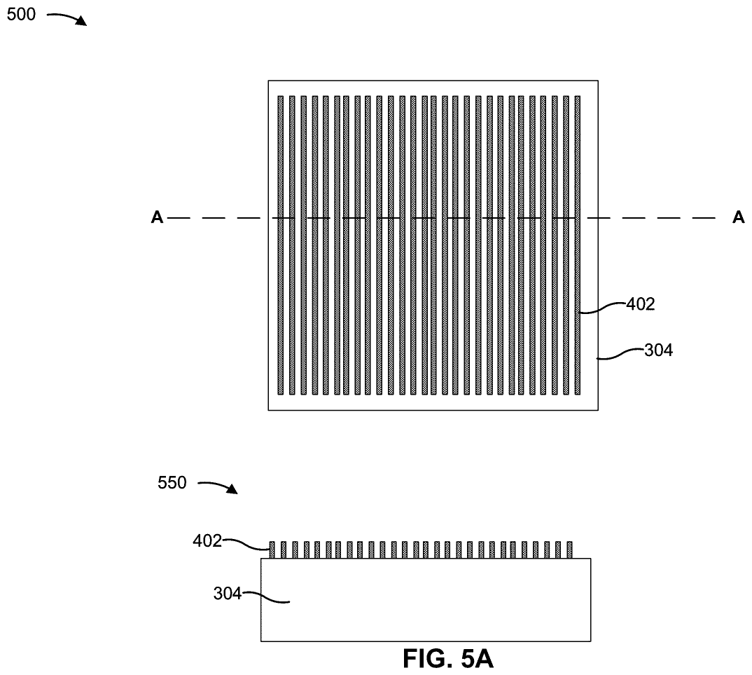

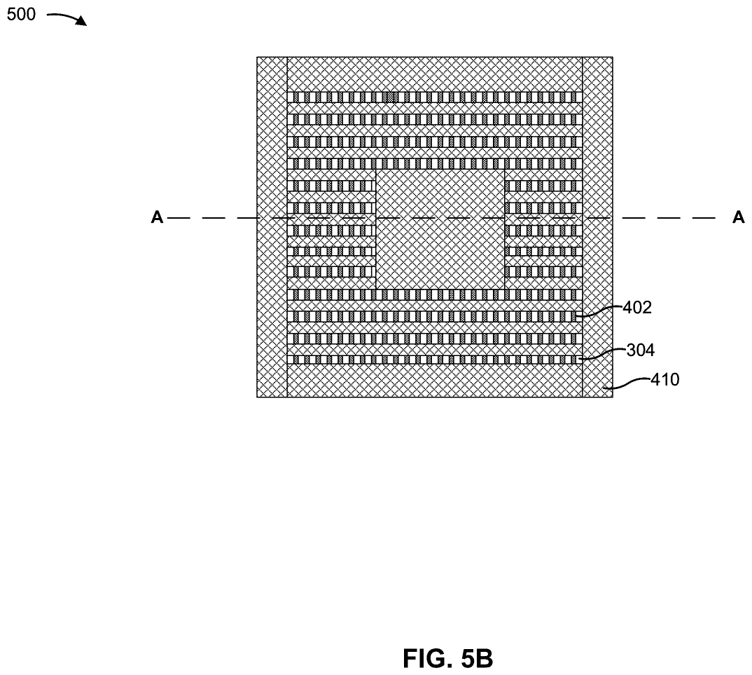

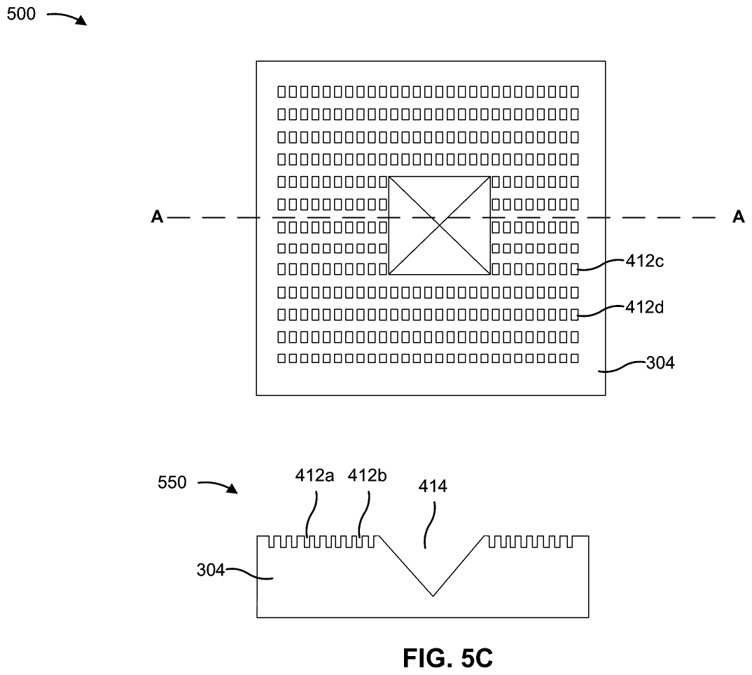

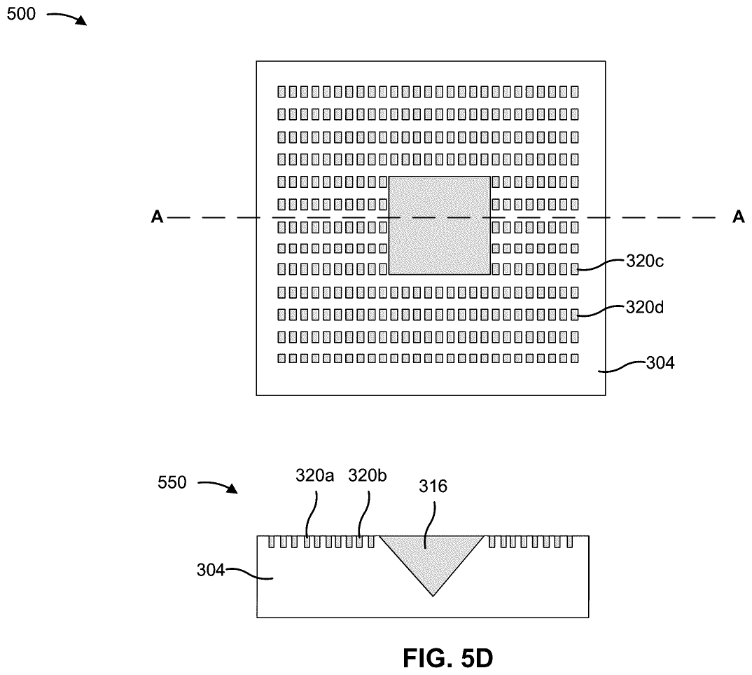

FIGS. 5A-5D are diagrams of an example implementation 500 described herein. The example implementation 500 may be an example process or method for forming the pixel array 300. The example implementation 500 may include a patterning technique for forming the array of nanoscale structures 320 of the pixel array 300. The patterning technique described in connection with FIGS. 5A-5C results in nanoscale structures 320 that are approximately spaced at regular intervals.

FIG. 5A illustrates a top-down view of the pixel array for example implementation 500 and a cross-sectional view 550 along the line AA. As shown in FIG. 5A, the example process for forming the pixel array may be performed in connection with a substrate 304 and a patterned hardmask layer 402. The hardmask layer 402 may be patterned as described in connection with FIGS. 4A-4J.

As shown in FIG. 5B, a photoresist layer 410 may be formed over the substrate 304. For example, the deposition tool 102 may form the photoresist layer 410 over and/or on the frontside surface of the substrate 304 (e.g., over the hardmask layer 402 and exposed surfaces of the substrate 304). As further shown in FIG. 5B, the exposure tool 104 may expose the photoresist layer 410 to a radiation source to form a pattern on the photoresist layer 410, and the developer tool 106 may develop and remove portions of the photoresist layer 410 to expose the pattern. For example, the pattern may divide a third rectangular pattern of the hardmask layer 402 such that exposed potions of the substrate 304 have cross-sections (e.g., in the top-down view) that are approximately square. Additionally, as shown in FIG. 4B, the pattern may provide for a base of an HA structure 316.

In some implementations, as shown in FIG. 5B, the pattern of the photoresist layer 410 may extend along a boundary corresponding to the isolation structure (not shown). Accordingly, the isolation structure is formed before the nanoscale structures 320. Alternatively, the isolation structure may be formed after the nanoscale structures 320 are formed.

FIGS. 5C and 5D illustrate a top-down view of the pixel array for example implementation 500 and a cross-sectional view 550 along the line AA. As shown in FIG. 5C, a portion of the substrate 304 may be removed. For example, the etch tool 108 may use a wet etch technique, a dry etch technique, a plasma-enhanced etch technique, and/or another type of etch technique to etch the substrate 304. The etch tool 108 may etch exposed portions of the substrate 304 according to the pattern of the photoresist layer 410. As a result, an array of nanoscale holes 412 (e.g., a nanoscale hole 412a, a nanoscale hole 412b, a nanoscale hole 412c, a nanoscale hole 412d, and a nanoscale hole 412e) are formed in the substrate 304.

As further shown in FIG. 5C, the photoresist removal tool 114 may remove the remaining portions of the photoresist layer 410 (e.g., using a chemical stripper, a plasma asher, and/or another technique) after the etch tool 108 removes the portion of the substrate 304. Additionally, as shown in FIG. 5C, the hardmask layer 402 may be removed. For example, the etch tool 108 may use a wet etch technique, a dry etch technique, a plasma-enhanced etch technique, and/or another type of etch technique to etch the hardmask layer 402. As further shown in FIG. 5C, an approximately pyramidal recess 414 may be formed (e.g., using another cycle of photolithography to etch a portion of the substrate 304 corresponding to the pyramidal recess 414).

As shown in FIG. 5D, the nanoscale holes 412 may be filled with dielectric material to form an array of nanoscale structures 320. The deposition tool 102 may deposit the dielectric material using a spin-coating technique, a CVD technique, a PVD technique, an ALD technique, and/or another deposition technique. Additionally, the pyramidal recess 414 may be filled with dielectric material to form an HA structure 316. In some implementations, the dielectric material may overflow the nanoscale holes 412 and the pyramidal recess 414 such that the planarization tool 110 removes dielectric material outside of the nanoscale holes 412 and the pyramidal recess 414 using a CMP technique.

In the example implementation 500, the array of nanoscale structures 320 and the HA structure 316 comprise the same dielectric material (or combination of materials that function as a dielectric). Alternatively, the array of nanoscale structures 320 may be filled with a first dielectric material (or combination of materials) before a subsequent cycle of photolithography to form the pyramidal recess 414. Accordingly, the pyramidal recess 414 may be filled with a second dielectric material (or combination of materials) such that the array of nanoscale structures 320 and the HA structure 316 are formed of different materials (or combinations of materials).

The HA structure 316 refracts NIR light toward the photodiode (not shown) of the pixel sensor. As a result, the HA structure 316 increases QE of the pixel sensor for NIR light. Additionally, because the array of nanoscale holes 412 are smaller, the nanoscale structures 320 refract visible light toward the photodiode (not shown) of the pixel sensor. As a result, the array of nanoscale structures 320 increases QE of the pixel sensor for visible light.

As indicated above, FIGS. 5A-5D are provided as an example. Other examples may differ from what is described with regard to FIGS. 5A-5D. For example, as described in connection with FIGS. 4A-4M, a first material 404 may be patterned with smaller widths w1 and w2. As a result, a rectangular pattern of a second material 406 may be extended into the hardmask layer 402, without deposition of the third material 408, while still resulting in the nanoscale structures 320.

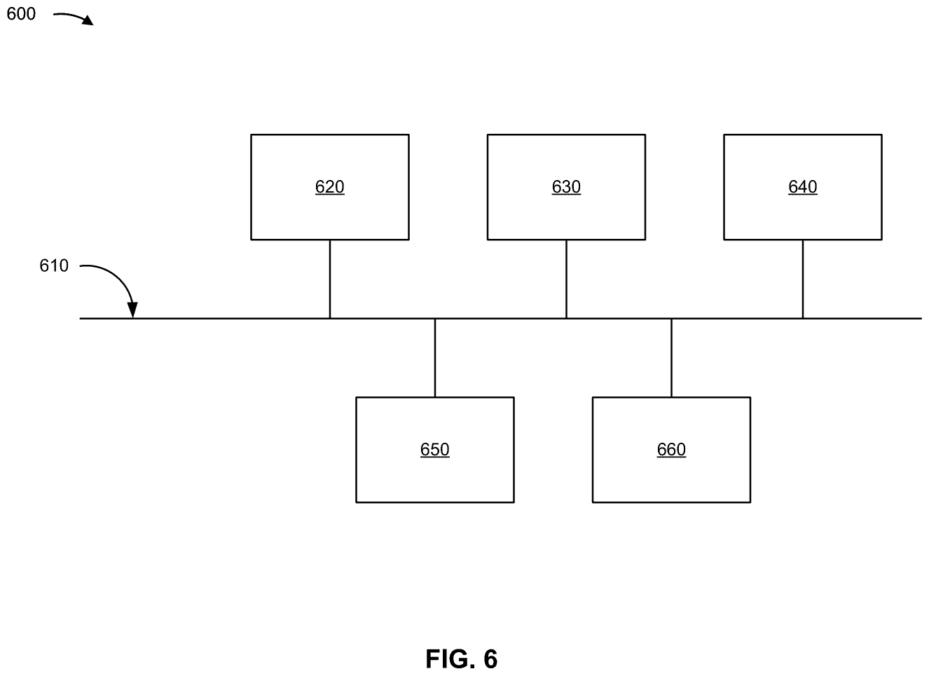

FIG. 6 is a diagram of example components of a device 600 described herein. In some implementations, one or more of the semiconductor processing tools 102-116 and/or the wafer/die transport tool 118 may include one or more devices 600 and/or one or more components of device 600. As shown in FIG. 6, device 600 may include a bus 610, a processor 620, a memory 630, an input component 640, an output component 650, and a communication component 660.

Bus 610 may include one or more components that enable wired and/or wireless communication among the components of device 600. Bus 610 may couple together two or more components of FIG. 6, such as via operative coupling, communicative coupling, electronic coupling, and/or electric coupling. Processor 620 may include a central processing unit, a graphics processing unit, a microprocessor, a controller, a microcontroller, a digital signal processor, a field-programmable gate array, an application-specific integrated circuit, and/or another type of processing component. Processor 620 is implemented in hardware, firmware, or a combination of hardware and software. In some implementations, processor 620 may include one or more processors capable of being programmed to perform one or more operations or processes described elsewhere herein.

Memory 630 may include volatile and/or nonvolatile memory. For example, memory 630 may include random access memory (RAM), read only memory (ROM), a hard disk drive, and/or another type of memory (e.g., a flash memory, a magnetic memory, and/or an optical memory). Memory 630 may include internal memory (e.g., RAM, ROM, or a hard disk drive) and/or removable memory (e.g., removable via a universal serial bus connection). Memory 630 may be a non-transitory computer-readable medium. Memory 630 stores information, instructions, and/or software (e.g., one or more software applications) related to the operation of device 600. In some implementations, memory 630 may include one or more memories that are coupled to one or more processors (e.g., processor 620), such as via bus 610.

Input component 640 enables device 600 to receive input, such as user input and/or sensed input. For example, input component 640 may include a touch screen, a keyboard, a keypad, a mouse, a button, a microphone, a switch, a sensor, a global positioning system sensor, an accelerometer, a gyroscope, and/or an actuator. Output component 650 enables device 600 to provide output, such as via a display, a speaker, and/or a light-emitting diode. Communication component 660 enables device 600 to communicate with other devices via a wired connection and/or a wireless connection. For example, communication component 660 may include a receiver, a transmitter, a transceiver, a modem, a network interface card, and/or an antenna.

Device 600 may perform one or more operations or processes described herein. For example, a non-transitory computer-readable medium (e.g., memory 630) may store a set of instructions (e.g., one or more instructions or code) for execution by processor 620. Processor 620 may execute the set of instructions to perform one or more operations or processes described herein. In some implementations, execution of the set of instructions, by one or more processors 620, causes the one or more processors 620 and/or the device 600 to perform one or more operations or processes described herein. In some implementations, hardwired circuitry is used instead of or in combination with the instructions to perform one or more operations or processes described herein. Additionally, or alternatively, processor 620 may be configured to perform one or more operations or processes described herein. Thus, implementations described herein are not limited to any specific combination of hardware circuitry and software.

The number and arrangement of components shown in FIG. 6 are provided as an example. Device 600 may include additional components, fewer components, different components, or differently arranged components than those shown in FIG. 6. Additionally, or alternatively, a set of components (e.g., one or more components) of device 600 may perform one or more functions described as being performed by another set of components of device 600.

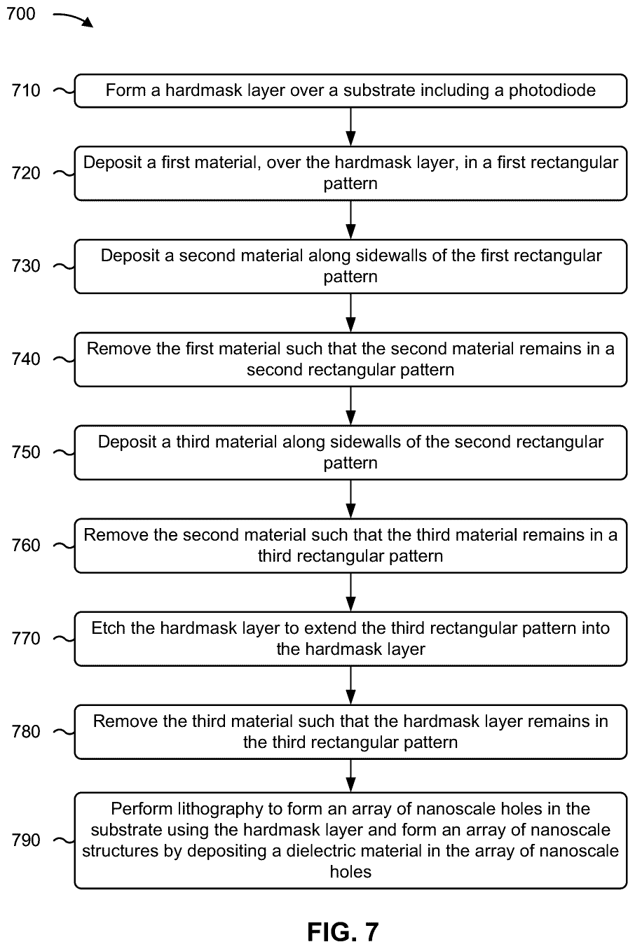

FIG. 7 is a flowchart of an example process 700 associated with forming nanoscale holes for pixel sensors. In some implementations, one or more process blocks of FIG. 7 are performed by one or more semiconductor processing tools (e.g., one or more of the semiconductor processing tools 102-116). Additionally, or alternatively, one or more process blocks of FIG. 7 may be performed by one or more components of device 600, such as processor 620, memory 630, input component 640, output component 650, and/or communication component 660.

As shown in FIG. 7, process 700 may include forming a hardmask layer over a substrate including a photodiode (block 710). For example, one or more of the semiconductor processing tools 102-116 may form a hardmask layer 402 over a substrate 304 including a photodiode 306, as described herein.

As further shown in FIG. 7, process 700 may include depositing a first material, over the hardmask layer, in a first rectangular pattern (block 720). For example, one or more of the semiconductor processing tools 102-116 may deposit a first material 404, over the hardmask layer 402, in a first rectangular pattern, as described herein.

As further shown in FIG. 7, process 700 may include depositing a second material along sidewalls of the first rectangular pattern (block 730). For example, one or more of the semiconductor processing tools 102-116 may deposit a second material 406 along sidewalls of the first rectangular pattern, as described herein.

As further shown in FIG. 7, process 700 may include removing the first material such that the second material remains in a second rectangular pattern (block 740). For example, one or more of the semiconductor processing tools 102-116 may remove the first material 404 such that the second material 406 remains in a second rectangular pattern, as described herein.

As further shown in FIG. 7, process 700 may include depositing a third material along sidewalls of the second rectangular pattern (block 750). For example, one or more of the semiconductor processing tools 102-116 may deposit a third material 408 along sidewalls of the second rectangular pattern, as described herein.

As further shown in FIG. 7, process 700 may include removing the second material such that the third material remains in a third rectangular pattern (block 760). For example, one or more of the semiconductor processing tools 102-116 may remove the second material 406 such that the third material 408 remains in a third rectangular pattern, as described herein.

As further shown in FIG. 7, process 700 may include etching the hardmask layer to extend the third rectangular pattern into the hardmask layer (block 770). For example, one or more of the semiconductor processing tools 102-116 may etch the hardmask layer 402 to extend the third rectangular pattern into the hardmask layer 402, as described herein.

As further shown in FIG. 7, process 700 may include removing the third material such that the hardmask layer remains in the third rectangular pattern (block 780). For example, one or more of the semiconductor processing tools 102-116 may remove the third material 408 such that the hardmask layer 402 remains in the third rectangular pattern, as described herein.

As further shown in FIG. 7, process 700 may include performing lithography to form an array of nanoscale holes in the substrate using the hardmask layer and forming an array of nanoscale structures by depositing a dielectric material in the array of nanoscale holes (block 790). For example, one or more of the semiconductor processing tools 102-116 may perform lithography to form an array of nanoscale holes 412 in the substrate 304 using the hardmask layer 402 and may form an array of nanoscale structures 320 by depositing a dielectric material in the array of nanoscale holes 412, as described herein.

Process 700 may include additional implementations, such as any single implementation or any combination of implementations described below and/or in connection with one or more other processes described elsewhere herein.

In a first implementation, the first material 404 has a width that is in a range from approximately 50 nm to approximately 80 nm.

In a second implementation, alone or in combination with the first implementation, the second material 406 has a width that is in a range from approximately 10 nm to approximately 40 nm.

In a third implementation, alone or in combination with one or more of the first and second implementations, the third material 408 has a width that is in a range from approximately 10 nm to approximately 40 nm.

In a fourth implementation, alone or in combination with one or more of the first through third implementations, performing the lithography further includes performing the lithography to etch a pyramidal recess 414 into the substrate 304.

In a fifth implementation, alone or in combination with one or more of the first through fourth implementations, process 700 includes forming an HA structure 316 by depositing an additional dielectric material according to the pyramidal recess 414.

In a sixth implementation, alone or in combination with one or more of the first through fifth implementations, performing the lithography includes forming a photoresist layer 410, patterning the array of nanoscale holes 412 using the photoresist layer 410, and removing the photoresist layer 410.

In a seventh implementation, alone or in combination with one or more of the first through sixth implementations, process 700 includes removing the third material 408 after forming the array of nanoscale holes 412.

In an eighth implementation, alone or in combination with one or more of the first through seventh implementations, the first material includes a metal.

In a ninth implementation, alone or in combination with one or more of the first through eighth implementations, the second material includes a nitride.

In a tenth implementation, alone or in combination with one or more of the first through ninth implementations, the third material includes a metal or an oxide.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, forming an array of nanoscale structures over photodiodes of a pixel array improves QE for shorter wavelengths of light, such as green light and blue light. The nanoscale structures may be used without HA structures (e.g., when the pixel array is configured only for visible light) or may at least partially surround HA structures (e.g., when the pixel array is configured both for visible light and NIR light). Additionally, the array of nanoscale structures may be formed using photolithography such that the nanoscale structures are approximately spaced at regular intervals. Therefore, QE for the pixel array is improved more than if the array of nanoscale structures were to be formed using a random (or quasi-random) process, such as DSA.

As described in greater detail above, some implementations described herein provide a semiconductor structure. The semiconductor structure includes a photodiode within a substrate. The semiconductor structure includes a high absorption (HA) structure over the photodiode and configured to reflect infrared light toward the photodiode. The semiconductor structure includes an array of nanoscale structures at least partially surrounding the HA structure and configured to reflect visible light toward the photodiode. The array of nanoscale structures are approximately spaced at regular intervals.

As described in greater detail above, some implementations described herein provide a method. The method includes forming a hardmask layer over a substrate including a photodiode. The method includes depositing a first material, over the hardmask layer, in a first rectangular pattern. The method includes depositing a second material along sidewalls of the first rectangular pattern. The method includes removing the first material such that the second material remains in a second rectangular pattern. The method includes depositing a third material along sidewalls of the second rectangular pattern. The method includes removing the second material such that the third material remains in a third rectangular pattern. The method includes etching the hardmask layer to extend the third rectangular pattern into the hardmask layer. The method includes removing the third material such that the hardmask layer remains in the third rectangular pattern. The method includes performing lithography to form an array of nanoscale holes in the substrate using the hardmask layer. The method includes forming an array of nanoscale structures by depositing a dielectric material in the array of nanoscale holes.

As described in greater detail above, some implementations described herein provide a semiconductor structure. The semiconductor structure includes a photodiode within a substrate. The semiconductor structure includes an array of nanoscale structures over the photodiode and configured to reflect visible light toward the photodiode. The array of nanoscale structures are approximately spaced at regular intervals.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a photodiode within a substrate;
a high absorption (HA) structure over the photodiode and configured to reflect infrared light toward the photodiode; and
an array of nanoscale structures at least partially surrounding the HA structure and configured to reflect visible light toward the photodiode,
wherein the array of nanoscale structures are approximately spaced at regular intervals.

2. The semiconductor structure of claim 1, wherein each nanoscale structure has a width that is in a range from approximately 10 nanometers (nm) to approximately 40 nm.

3. The semiconductor structure of claim 1, wherein each nanoscale structure has a cross-section that is approximately square.

4. The semiconductor structure of claim 1, wherein each nanoscale structure is at a distance from an adjacent nanoscale structure in a range from approximately 10 nanometers (nm) to approximately 40 nm.

5. The semiconductor structure of claim 1, wherein the HA structure has an approximately pyramidal shape.

6. The semiconductor structure of claim 1, further comprising:
an isolation structure surrounding the photodiode,
wherein a ratio of a depth of the isolation structure from a top of the substrate to a depth of the photodiode from the top of substrate is in a range from approximately 0.5 to approximately 0.8.

7. A method, comprising:
forming a hardmask layer over a substrate including a photodiode;
depositing a first material, over the hardmask layer, in a first rectangular pattern;
depositing a second material along sidewalls of the first rectangular pattern;
removing the first material such that the second material remains in a second rectangular pattern;
depositing a third material along sidewalls of the second rectangular pattern;
removing the second material such that the third material remains in a third rectangular pattern;
etching the hardmask layer to extend the third rectangular pattern into the hardmask layer;
removing the third material such that the hardmask layer remains in the third rectangular pattern;
performing lithography to form an array of nanoscale holes in the substrate using the hardmask layer; and
forming an array of nanoscale structures by depositing a dielectric material in the array of nanoscale holes.

8. The method of claim 7, wherein the first material has a width that is in a range from approximately 50 nanometers (nm) to approximately 80 nm.

9. The method of claim 7, wherein the second material has a width that is in a range from approximately 10 nanometers (nm) to approximately 40 nm.

10. The method of claim 7, wherein the third material has a width that is in a range from approximately 10 nanometers (nm) to approximately 40 nm.

11. The method of claim 7, wherein performing the lithography further comprises:
performing the lithography to etch a pyramidal pattern into the substrate.

12. The method of claim 11, further comprising:
forming a high absorption (HA) structure by depositing an additional dielectric material according to the pyramidal pattern.

13. The method of claim 7, wherein performing the lithography comprises:
forming a photoresist layer;
patterning the array of nanoscale holes using the photoresist layer; and
removing the photoresist layer.

14. The method of claim 11, further comprising:
removing the third material after forming the array of nanoscale holes.

15. The method of claim 7, wherein the first material comprises a metal.

16. The method of claim 7, wherein the second material comprises a nitride.

17. The method of claim 7, wherein the third material comprises a metal or an oxide.

18. A semiconductor structure, comprising:
a photodiode within a substrate; and
an array of nanoscale structures over the photodiode and configured to reflect visible light toward the photodiode,
wherein the array of nanoscale structures are approximately spaced at regular intervals.

19. The semiconductor structure of claim 18, wherein the array of nanoscale structures are filled with a dielectric material.

20. The semiconductor structure of claim 18, further comprising:
an isolation structure surrounding the photodiode,
wherein a ratio of a depth of the isolation structure from a top of the substrate to a depth of the photodiode from the top of substrate is in a range from approximately 0.5 to approximately 0.8.
